(19) United States
(12) Patent Application Publication
(10) Pub. No.: US 2010/0147380 A1
(43) Pub. Date: Jun. 17, 2010

(54) Hybrid Photovoltaic Cell Using Amorphous Silicon Germanium Absorbers and Wide Bandgap Dopant Layers

(75) Inventors: Samuel Dacke Harkness, IV, Berkeley, CA (US); Hans Jurgen Richter, Palo Alto, CA (US)

Correspondence Address: PIETRAGALLO GORDON ALFANO BOSICK & RASPANTI, LLP, ONE OXFORD CENTRE, 38TH FLOOR, 301 GRANT STREET, PITTSBURGH, PA, 15219-6404, US

(73) Assignee: Seagate Technology LLC, Scotts Valley, CA (US)

(21) Appl. No.: 12/336,673

(22) Filed: Dec. 17, 2008

(51) Int. Cl. H01L 31/00; C23C 14/35

(52) U.S. Cl. 136/258; 136/261; 204/192.15

(57) ABSTRACT

A photovoltaic apparatus includes a p-layer having a bandgap greater than about 2 eV, an n-layer having a bandgap greater than about 2 eV, and an absorber layer between the p-layer and the n-layer, wherein the absorber layer includes SiGe. The ratio of Si to Ge in the absorber layer can be selected to obtain an absorber bandgap between about 1.1 and about 1.4 eV.

### BACKGROUND

This invention relates to photovoltaic devices and methods for fabricating such devices.

Photovoltaic devices, also referred to as solar cells, convert light directly into electricity. The majority of photovoltaic devices use a semiconductor as an absorber layer with a well-defined bandgap, such as crystalline silicon with an energy bandgap Eg of 1.1 eV. Photovoltaic devices include layers of semiconductor materials with different electronic properties. One of the layers can be silicon that is “doped” with a small quantity of boron to give it a positive (or p-type) character. Another layer can be silicon doped with phosphorus to give it a negative (or n-type) character. The p and n layers can be adjacent to each other or separated by an intermediate layer, i. The interface, or junction, between these two layers contains an electric field. The intermediate layer of the p-i-n structure is left un-doped (i.e., intrinsic) and has the role of absorbing incident light. Since the i-layer is sandwiched between the p and the n regions, it experiences a high electrical field which drives charge separation and increases the efficiency of the solar cell.

When light (i.e., photons) hits the device, some of the photons are absorbed, freeing electrons and holes (i.e., carriers) in the absorber. If the photons have enough energy, the carriers will be driven out by the electric field and move through the silicon and into an external circuit.

Amorphous materials have been proposed for use in photovoltaic devices. Known amorphous silicon photovoltaic designs are limited in conversion efficiency owing to high recombination rates. This problem is primarily due to the presence of high numbers of defect carrier traps situated deep within the bandgap. Such traps forbid the efficient transfer, and thus separation of electric charges resulting in low carrier mobility. Two main sources of the defects include hydrogen microstructure, and incomplete dopant activation. In the case of the latter, the effect is responsible for poor transport characteristics widely seen in p-doped microcrystalline silicon. In fact, because of the general inability of sputter processing to generate microcrystallinity in thin film silicon, the dopant activation is virtually nil.

Another issue related to amorphous silicon designs is the inability to control the bandgap via alloy addition. This limits the possible capture of photons to those with energies greater than 1.8 eV. Amorphous germanium is an ideal candidate to alloy with the silicon since the bandgap is about 1.0 eV. However, although silicon and germanium are miscible, a problem arises during fabrication associated with the preferred deposition technique, chemical vapor deposition (CVD). Competitive reaction rates lead to poor optoelectronic properties with increasing germanium concentration. The industry-wide solution thus far has been to control the bandgap with partial crystallinity since the presence of crystal silicon leads to a lower bandgap, since the bandgaps are approximately 1.8 eV for amorphous silicon, and 1.1 eV for crystalline silicon. While this approach is effective, it necessitates thicker absorber regions since the increased crystalline content drastically decreases the effective absorption coefficient of the material.

### SUMMARY

In a first aspect, the invention provides a photovoltaic apparatus including a p-layer having a bandgap greater than about 2 eV, an n-layer having a bandgap greater than about 2 eV, and an absorber layer between the p-layer and the n-layer, wherein the absorber layer includes SiGe. The ratio of Si to Ge in the absorber layer can be selected to obtain an absorber bandgap between about 1.1 and about 1.4 eV.

In another aspect, the invention provides a photovoltaic apparatus including a ZnO p-layer, an ZnO n-layer, and an absorber layer between the ZnO p-layer and the ZnO n-layer, wherein the absorber layer comprises amorphous silicon.

In another aspect, the invention provides a method of making an absorber layer in a photovoltaic device. The method includes: providing a substrate, and using dc-magnetron or rf-magnetron sputtering to deposit an SiGe absorber layer on the substrate, wherein the sputtering is performed with a substrate temperature of less than about 300° C.; with an AR sputter gas pressure of less than about 10 mTorr, in a partial hydrogen environment, and at a deposition rate of less than about 10 nm/s.

### BRIEF DESCRIPTION OF THE DRAWINGS

FIG. 1 is a schematic diagram of a photovoltaic device constructed in accordance with an aspect of the invention.

FIG. 2 is a schematic diagram of a photovoltaic device constructed in accordance with another aspect of the invention.

FIG. 3 is a schematic diagram of a photovoltaic device constructed in accordance with another aspect of the invention.

FIG. 4 is a schematic diagram of a photovoltaic device constructed in accordance with another aspect of the invention.

FIG. 5 is an equivalent circuit diagram for a drift limited solar cell.

### DETAILED DESCRIPTION OF THE INVENTION

In one aspect, this invention provides a photovoltaic device that utilizes wide bandgap semiconductor materials to drive the open circuit voltage potential of the device. In another aspect, this invention provides a method for producing a photovoltaic device that enables physical vapor deposition (PVD) for the formation of silicon-germanium alloy absorber layers.

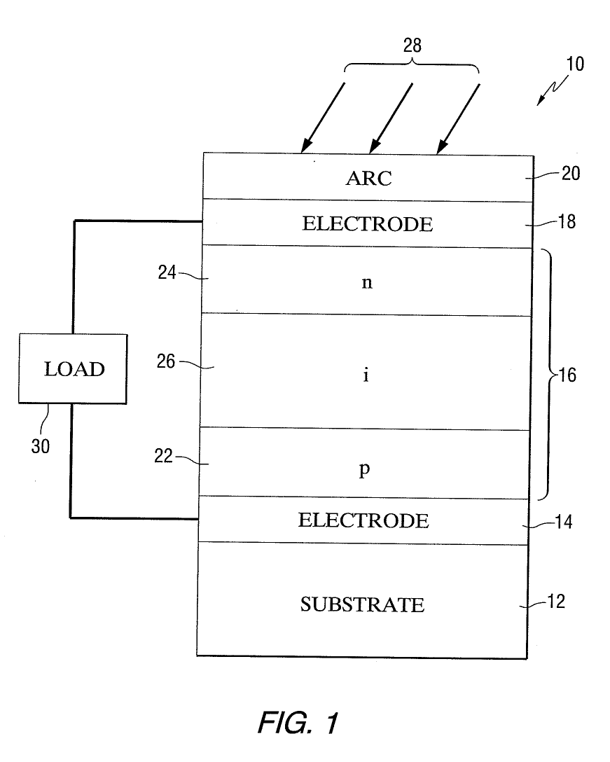

FIG. 1 is a schematic diagram of a photovoltaic device 10 constructed in accordance with an aspect of the invention. The device includes a substrate 12, a first electrode 14, a p-i-n structure 16, a second electrode 18, and an anti-reflection coating 20. The p-i-n structure includes a p-doped layer 22 and an n-doped layer 24 on opposite sides of an intrinsic layer 26. The thin film structure of FIG. 1 is configured in a well-known p-i-n alignment. In this description, the p-doped layer is also referred to as a p-layer and the n-doped layer is also referred to as an n-layer.

When light 28 (i.e., photons) hits the device, some of the photons are absorbed, freeing electrons and holes (i.e., carriers) in the absorber. If the photons have enough energy, the carriers will be driven out by the electric field and move through the silicon and into an external circuit, illustrated as the load 30.

In one example, the substrate can be, for example, glass. The first electrode can be, for example, aluminum or silver. The second electrode can be, for example, silver. The anti-reflective coating can be, for example, MgF. The p-doped layer can be, for example, ZnO doped with phosphorous. The n-doped layer can be, for example, ZnO doped with aluminum. The ZnO doped layers can further include MgO to form an ZnₓMg₁₋ₓO alloy.

Photovoltaic devices constructed in accordance with one aspect of the invention include an SiₓGe₍₁₋ₓ₎ alloy in the intrinsic layer. The composition (i.e., the ratio of Si to Ge) is selected by tuning the value of ‘x’ to achieve a desired bandgap in the absorber material. A preferred bandgap range is between about 1.0 and about 1.4 eV.

To reduce the effect of defects and to promote high optoelectronic quality, the intrinsic layer material can be prepared using either dc-magnetron, or rf-magnetron sputtering. The target used in the sputter process can be an alloy target having a stoichiometric ratio of silicon to germanium similar to that desired in the finished film. To further reduce the defect level, the target should have a purity level of 99.999% or greater.

Preferred process conditions during growth of the absorber layer include: low substrate temperature (e.g., <300° C.); low sputter gas pressure (e.g., Ar<10 mTorr) in a partial hydrogen environment sufficient in volume ratio to fully reduce the dangling bond density; and relatively low deposition rate (e.g., <10 nm/s).

The materials selection and processing can be controlled to optimize the intrinsic layer to the desired bandgap while not compromising the absorption coefficient. In a SiGe alloy intrinsic layer, as germanium content is increased in the alloy, the absorption becomes stronger. The absorption can be set to allow full extinction of the incoming solar radiation within an intrinsic absorber having a thickness of about 500 nm. This compares to an intrinsic absorber thickness of about 3600 nm for conventional amorphous silicon designs.

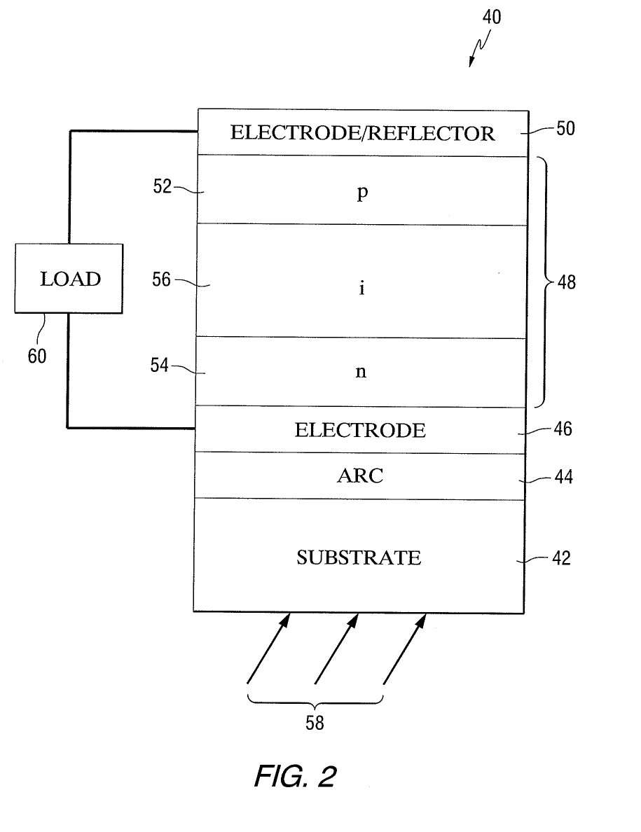

The order of the layers in the device of FIG. 1 can be reversed and created in a “superstrate” configuration. FIG. 2 is a schematic diagram of a photovoltaic device 40 constructed in accordance with another aspect of the invention. The device includes a substrate 42, a first electrode 44, a p-i-n structure 46, a second electrode 48, and an anti- reflection coating 50. The p-i-n structure includes a p-doped layer 52 and an n-doped layer 54 on opposite sides of an intrinsic layer 56. The materials used for the layers in the example of FIG. 2 can be similar to the example materials described for the layers of the device of FIG. 1.

When light 58 (i.e., photons) hits the device, some of the photons are absorbed, freeing electrons and holes (i.e., carriers) in the absorber. If the photons have enough energy, the carriers will be driven out by the electric field and move through the silicon and into an external circuit, illustrated as the load 60.

To better capture the entire solar spectrum, multiple junction cells can be fabricated in series, with each p-i-n structure including a SiₓGe₍₁₋ₓ₎ alloy in the intrinsic layer. The composition (i.e., the ratio of Si to GE) in the intrinsic layers would be selected by tuning the value of ‘x’ to achieve a desired bandgap in the absorber material.

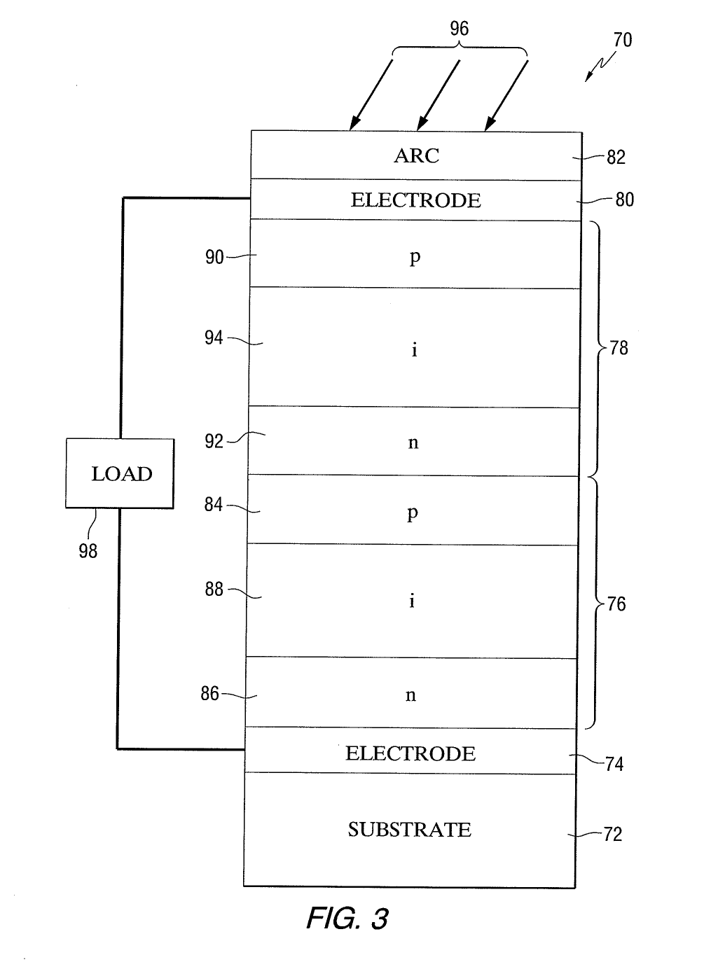

FIG. 3 is a schematic diagram of a multiple junction photovoltaic device 70 constructed in accordance with another aspect of the invention. The device includes a substrate 72, a first electrode 74, a first p-i-n structure 76, a second p-i-n structure 78, a second electrode 80, and an anti-reflection coating 82. The first p-i-n structure includes a p-doped layer 84 and an n-doped layer 86 on opposite sides of an intrinsic layer 88. The second p-i-n structure includes a p-doped layer 90 and an n-doped layer 92 on opposite sides of an intrinsic layer 94. The intrinsic layers can be a SiGe alloy as described above for FIG. 1.

When light 96 (i.e., photons) hits the device, some of the photons are absorbed, freeing electrons and holes (i.e., carriers) in the absorber. If the photons have enough energy, the carriers will be driven out by the electric field and move through the silicon and into an external circuit, illustrated as the load 98. The intrinsic layer can be fabricated to have different bandgaps, and thus absorb different portions of the spectrum of incident light. The materials used for the layers in the example of FIG. 3 can be similar to the example materials described for the layers of the device of FIG. 1.

In a single absorber example, the composition of the absorber can be varied such that the high bandgap material (Si rich) is closer to the illuminated side and the low bandgap material (Ge rich) is further away from the illuminated side.

Another aspect of the invention involves the use of wide bandgap semiconductor materials to generate the built-in potential of the device. As used herein, a wide bandgap is a bandgap having an energy of greater than about 2 eV. This can be accomplished by doping select materials to form the n-doped and p-doped layers and positioning the doped layers on opposite sides of the absorber.

A preferred material for the n-layer is ZnO-2 wt % Al₂O₃. The carrier concentration and mobility can be controlled by adjusting the amount of aluminum activated onto the ZnO lattice. Dopant activation energies less than 0.5 eV are readily achieved along with preferred room temperature electron concentrations of greater than 1×10²⁰.

A preferred material for the p-layer is ZnO-2 wt % P₂O₅. Post thermal treatment of greater than 800° C. for 1 minute or longer may be required to render the material p-type with the desired hole carrier concentration (e.g., greater than 1×10¹⁸).

In another aspect, the invention relates to a photovoltaic device that includes an amorphous Si absorber. This aspect of the invention seeks to mitigate the effect of high recombination rates on the overall photovoltaic performance of cells comprised of amorphous materials using a reduction in the thickness of the absorber, and larger built-in potential fields. Such fields are derived from the difference in quasi-Fermi Energy levels associated with the constituent n-doped and p-doped layers. Reductions in thickness must be balanced against commensurate loss in absorption.

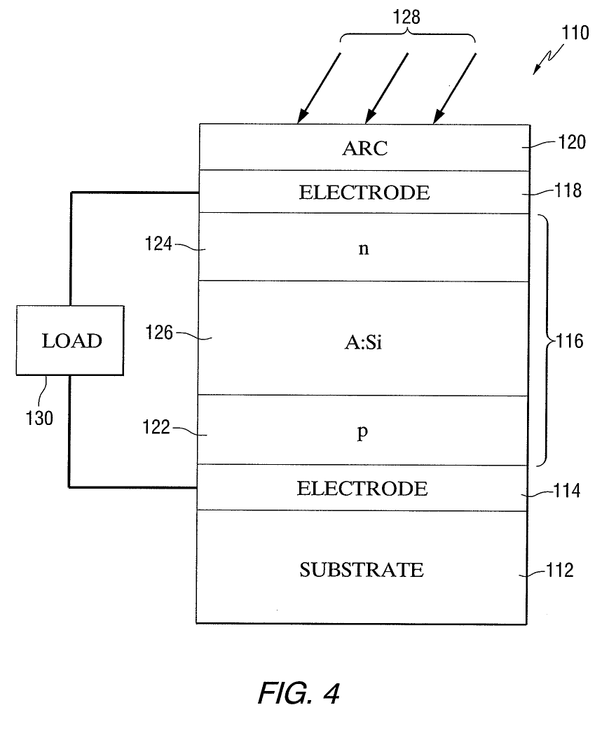

In one example, the invention encompasses a photovoltaic device that includes a combination of an amorphous Si absorber with ZnO layers, where the ZnO layers serve as the p and the n layers. Amorphous Si (a:Si) is known to be difficult to dope if it is made by sputtering. ZnO is a wide bandgap material with an energy gap of about 3.3 eV. Consequently, the driving field provided by the ZnO is higher than for standard a:Si. FIG. 4 is a schematic diagram of a photovoltaic device constructed in accordance with this aspect of the invention. The ZnO layers can be doped as described above.

The photovoltaic device 110 of FIG. 4 includes a substrate 112, a first electrode 114, a p-i-n structure 116, a second electrode 118, and an anti-reflection coating 120. The p-i-n structure includes a p-doped layer 122 and an n-doped layer 124 on opposite sides of an intrinsic layer 126. The thin film structure of FIG. 1 is configured in a well-known p-i-n alignment. The intrinsic layer is comprised of amorphous silicon. The intrinsic layer bandgap range is between about 1.2 eV and about 1.7 eV.

When light 128 (i.e., photons) hits the device, some of the photons are absorbed, freeing electrons and holes (i.e., carriers) in the absorber. If the photons have enough energy, the carriers will be driven out by the electric field and move through the silicon and into an external circuit, illustrated as the load 130.

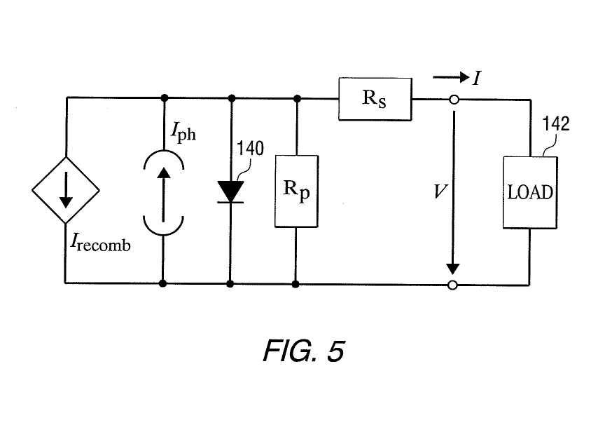

The device in FIG. 4 is a drift limited photovoltaic device. FIG. 5 is an equivalent circuit diagram for a drift limited solar cell. The current resulting from the conversion of incident light is the photovoltaic current Iₚₕ. The recombination current I_{recomb} is characteristic for a:Si cells. The forward junction voltage of the diode 130 established the open circuit output voltage of the device. Rₚ represents internal parallel resistance. Rₛ represents internal series resistance. I is the output current delivered to the load 132 and V is the output voltage seen by the load.

The short circuit current and the fill factor for p-i-n a:Si solar cells with low carrier mobility are limited by carrier drift and not by diffusion processes as in standard crystalline Si (c:Si) cells. As used herein, the power capability of the device is seen on the current-voltage (I-V) curve or trace as: P(max)/P(ideal).

In this case, a simplification exists for the short circuit current J_{sc}. As to be expected, the short circuit current depends on the mobility μ, the thickness of the intrinsic layer δᵢ, the carrier lifetime τ, and the applied field or voltage V:

$${J}_{sc}^{′} = {J}_{sc} ( 1 - \frac{{δ}_{i}^{2}}{μ τ ( {V}_{bi} - V )} ) . \qquad ( 1 )$$

Here V_{bi} is the built-in voltage which corresponds to the amount of band bending in the semiconductor. The voltage is applied externally to match the maximum power output as observed on the I-V trace. For the estimate here, the series resistance will be implicitly absorbed in the analysis. That is, the series resistance is accounted for in the fill factor and thus does need separate definition. The product μτ is an average for holes and electrons. J_{sc} is the short circuit current density. It is the current density observed on a J-V (instead of I-V) trace where the voltage is zero.

Among other assumptions, the theory assumes a linear dependence of the carrier concentrations through the i-layer and a constant electric field. For a comparison of a normal a:Si cell and an a:Si/ZnO cell, it is reasonable to assume the same thickness and the same product μτ and therefore no other information is required.

Normal a:Si cells have doped silicon layers surrounding the intrinsic layer and are used conventionally to drive the electric field responsible for charge separation.

A baseline can be obtained as follows. The fill factor is given by the following expression:

$$FF = {FF}_{0} ( 1 - {r}_{s} ) \\ where \\ {r}_{s} = \frac{{R}_{s}}{{V}_{0 c} / {I}_{sc}} . \qquad ( 2 )$$

In the equivalent circuit diagram, the effect of recombination is treated as a fictitious series resistor. Without this resistor, the fill factor is:

$${FF}_{0} = \frac{{v}_{oc} - ln ( {v}_{oc} + 0.72 )}{{v}_{oc} + 1} , where {v}_{oc} = \frac{{V}_{oc}}{{V}_{T}} \qquad ( 3 )$$

and where V_{T} is the temperature voltage (i.e., 25 mV).

According to published information, the equivalent series resistor that describes the recombination is:

$${R}_{sc} = {I}_{ph}^{- 1} \frac{{δ}_{i}^{2}}{μ τ ( {V}_{bi} - V )} \qquad ( 4 )$$

where the voltage difference was added back in.

The a:Si bandgap can be estimated using the ultimate efficiency limit, which considers the availability of the energy for conversion but not the radiation contribution. The radiation contribution is small compared to all other recombination mechanisms and can therefore be safely neglected, especially for poor cells like a:Si. Going from 1.65 eV to the optimum 1.1 eV for the absorber bandgap yields a gain of 19.6% for an air mass (AM) of 1.5. Cells having a bandgap >1.45 eV are considered to be poor as they “throw away” too much of the available sunlight. Air Mass 1.5 is a standard designation intended to simulate the atmospheric effects on the sun's irradiance in a location similar to, for example, California.

The product μτ is the same as for normal a:Si. The thickness of the intrinsic layer is assumed to be constant. The maximum fill factor is determined from equation (3). The total rₛ is the sum of r_{s,true} and r_{s,recomb}. R_{s,true} is assumed to stay constant. From this one gets r_{s,true}. R_{s,recomb} scales according to equation (4) with V=0, then r_{s,recomb} follows.

Photovoltaic devices constructed in accordance with an aspect of the invention can realize photovoltaic efficiency competitiveness with current state-of-the-art technologies including CIGS/CIS, and CdTe. (i.e., copper indium gallium diselenide, and copper indium diselenide).

An advantage of the disclosed design emerges in the form of the inherent environmental-friendliness both in starter materials as well as in the finished product. This fact, in combination with the thinner total stack thickness, makes the design a significant improvement in terms of cost-effectiveness for a solar cell implementation.

While the invention has been described in terms of several examples, it will be apparent to those skilled in the art that various changes can be made to the disclosed examples, without departing from the scope of the invention as set forth in the following claims. The implementations described above and other implementations are within the scope of the following claims.

1. A photovoltaic apparatus comprising:
a p-layer having a bandgap greater than about 2 eV;
an n-layer having a bandgap greater than about 2 eV; and
an absorber layer between the p-layer and the n-layer, wherein the absorber layer includes SiGe.

2. The photovoltaic apparatus of claim 1, wherein the ratio of Si to Ge in the absorber layer is selected to obtain an absorber bandgap between about 1.1 and about 1.4 eV.

3. The photovoltaic apparatus of claim 1, wherein the p-layer comprises ZnO, and the n-layer comprises ZnO.

4. The photovoltaic apparatus of claim 3, wherein the p-layer further comprises MgO and the n-layer further comprises MgO.

5. The photovoltaic apparatus of claim 1, wherein the p-layer has a thickness of about 10000 Å, the n-layer has a thickness of about 3000 Å, and the absorber layer has a thickness of about 5000 Å.

6. The photovoltaic apparatus of claim 1, further comprising:
a substrate; and
an electrically conductive layer on the substrate, wherein the wide bandgap n-layer is positioned on the electrically conductive layer.

7. A photovoltaic apparatus comprising:
a p-layer including ZnO;
an n-layer including ZnO; and
an absorber layer between the p-layer and the n-layer, wherein the absorber layer comprises amorphous silicon.

8. The photovoltaic apparatus of claim 7, wherein the p-layer further comprises P₂O₅.

9. The photovoltaic apparatus of claim 7, wherein the n-layer further comprises Al₂O₃.

10. The photovoltaic apparatus of claim 7, further comprising:
a substrate; and
an electrically conductive layer on the substrate, wherein one of the p-layer or the n-layer is positioned on the electrically conductive layer.

11. A method of making an absorber layer in a photovoltaic device, the method comprising:
providing a substrate; and
using dc-magnetron or rf-magnetron sputtering to deposit a SiGe absorber layer on the substrate, wherein the sputtering is performed with a substrate temperature of less than about 300° C.; with an AR sputter gas pressure of less than about 10 mTorr, in a partial hydrogen environment; and at a deposition rate of less than about 10 nm/s.

12. The method of claim 11, wherein the partial hydrogen environment has a sufficient volume ratio to fully reduce a dangling bond density.

13. The method of claim 11, wherein the sputtering uses an alloy target having a stoichiometric ratio of silicon to germanium similar to that desired in the absorber.

14. The method of claim 13, wherein the target has a purity level of 99.999% or greater.
